(19) United States
(12) Patent Application Publication
(10) Pub. No.: US 2024/0145653 A1
(43) Pub. Date: May 2, 2024

(54) DISPLAY DEVICE AND MANUFACTURING METHOD THEREOF

(71) Applicant: HANNSTAR DISPLAY CORPORATION, Taipei City (TW)

(72) Inventors: Chun-I Chu, Hsinchu County (TW); Yu-Chi Chiao, Taipei City (TW); Yung-Li Huang, Tainan City (TW); Hung-Ming Chang, Tainan City (TW); Cheng-Yu Lin, Miaoli County (TW); Huan-Hsun Hsieh, Hsinchu City (TW); CHeng-Pei Huang, Taipei City (TW)

(73) Assignee: HANNSTAR DISPLAY CORPORATION, Taipei City (TW)

(21) Appl. No.: 18/196,453

(22) Filed: May 12, 2023

(30) Foreign Application Priority Data
Oct. 27, 2022 (CN) 202211339758.9

(51) Int. Cl. H01L 33/62; H01L 25/075; H01L 33/44; H01L 33/50

(52) U.S. Cl. CPC H01L 33/62; H01L 25/0753; H01L 33/44; H01L 33/505; H01L 2933/0025; H01L 2933/0041; H01L 2933/0066

(57) ABSTRACT

A manufacturing method of a display device includes forming light emitting components on a first substrate, the light emitting components include a first side and a second side, and the second side is away from the first substrate; forming a circuit layer on the first substrate and on the second side of the light emitting components; forming a first protective layer on the circuit layer and forming an insulating layer on the first protective layer; removing the first substrate after forming a second substrate on the insulating layer; forming a black matrix layer on the first side of the light emitting components, and the black matrix layer includes openings; forming light conversion layers in the openings of the black matrix layer; forming a second protective layer on the black matrix layer and the light conversion layers; and forming a third substrate on the second protective layer.

### BACKGROUND OF THE INVENTION

### 1. Field of the Invention

The present invention relates to a display device and a manufacturing method thereof, and more particular to a display device having micro-light emitting diodes and a manufacturing method thereof.

### 2. Description of the Prior Art

The manufacturing method of the micro-light emitting diode (micro-LED) display device usually includes mass transfer of micro-LEDs in order to dispose micro-LEDs on the substrate. The precision and yield of the transfer process have always been a great difficulty in manufacturing micro-LED display device. Especially under the demand of high pixels per inch (PPI) design, it is a great challenge to manufacture micro-LED display devices by the mass transfer process.

### SUMMARY OF THE INVENTION

The technical problem to be solved by the present invention is improving the yield of manufacturing micro-light emitting diode display devices.

To solve the above technical problem, the present invention provides a manufacturing method of a display device which includes following steps: forming light emitting components on a first substrate, the light emitting components include a first side and a second side opposite to the first side, and the second side is away from the first substrate; forming a circuit layer on the first substrate and on the second side of the light emitting components; forming a first protective layer on the circuit layer and forming an insulating layer on the first protective layer; removing the first substrate after forming a second substrate on the insulating layer; forming a black matrix layer on the first side of the light emitting components, and the black matrix layer includes openings; forming light conversion layers in the openings of the black matrix layer; forming a second protective layer on the black matrix layer and the light conversion layers; and forming a third substrate on the second protective layer.

To solve the above technical problem, the present invention provides a display device which includes a first substrate, a second substrate, a first protective layer, light emitting components and a circuit layer. The second substrate is disposed opposite to the first substrate. The first protective layer is disposed between the first substrate and the second substrate, and the first protective layer includes recesses. The light emitting components are disposed in the recesses of the first protective layer. The circuit layer is disposed on the first protective layer and extending into the recesses, the circuit layer is electrically connected to the light emitting components, and a portion of the circuit layer is disposed between the light emitting components and the first protective layer.

In the display device and the manufacturing method thereof of the present invention, the light emitting components and the circuit layer are directly formed on the wafer. Therefore, the light emitting components do not need to be transferred to the circuit board, which can solve the problems of poor precision and poor yield introduced by the mass transfer process, and being beneficial to manufacturing high PPI display devices or flexible display devices.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 9 are schematic diagrams illustrating a manufacturing method of a display device according to a first embodiment of the present invention.

FIG. 10 is a schematic diagram illustrating a top view of a display mother board including display panel units in the first embodiment of the present invention.

FIG. 11 is a schematic diagram illustrating a top view of one of the display panel units according to the first embodiment of the present invention.

FIG. 12 is a flowchart of the manufacturing method of the display device according to the first embodiment of the present invention.

FIG. 13 is a schematic cross-sectional diagram illustrating the display device according to the first embodiment of the present invention.

FIG. 14 is a schematic cross-sectional diagram illustrating a display device according to a second embodiment of the present invention.

### DETAILED DESCRIPTION

To provide a better understanding of the present invention to those skilled in this field, preferred embodiments will be detailed as follows. The preferred embodiments of the present invention are illustrated in the accompanying drawings to elaborate on the contents and effects to be achieved. It should be noted that the drawings are simplified schematics, and therefore show only the components and combinations associated with the present invention, so as to provide a clearer description of the basic architecture or method of implementation. The components would be complex in reality. In addition, for ease of explanation, the components shown in the drawings may not represent their actual number, shape, and dimensions; details can be adjusted according to design requirements.

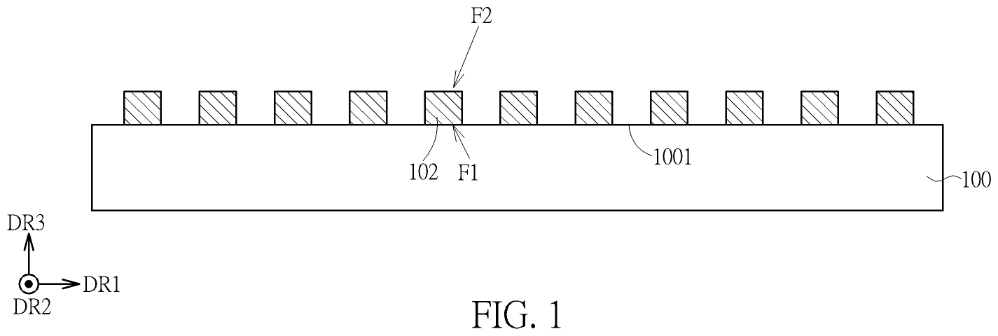

A direction DR1, a direction DR2 and a direction DR3 are shown in the following drawings. The direction DR3 may be a normal direction or a top view direction, and the direction DR3 can be perpendicular to a surface 1001 of a substrate 100 as shown in FIG. 1. The direction DR1 and the direction DR2 may be horizontal directions and perpendicular to the direction DR3. As shown in FIG. 1, the directions DR1 and DR2 can be parallel to the surface 1001 of the substrate 100, and the direction DR1 can be perpendicular to the direction DR2. The spatial relationship of structures can be described according to the directions DR1, DR2 and DR3 in the following drawings.

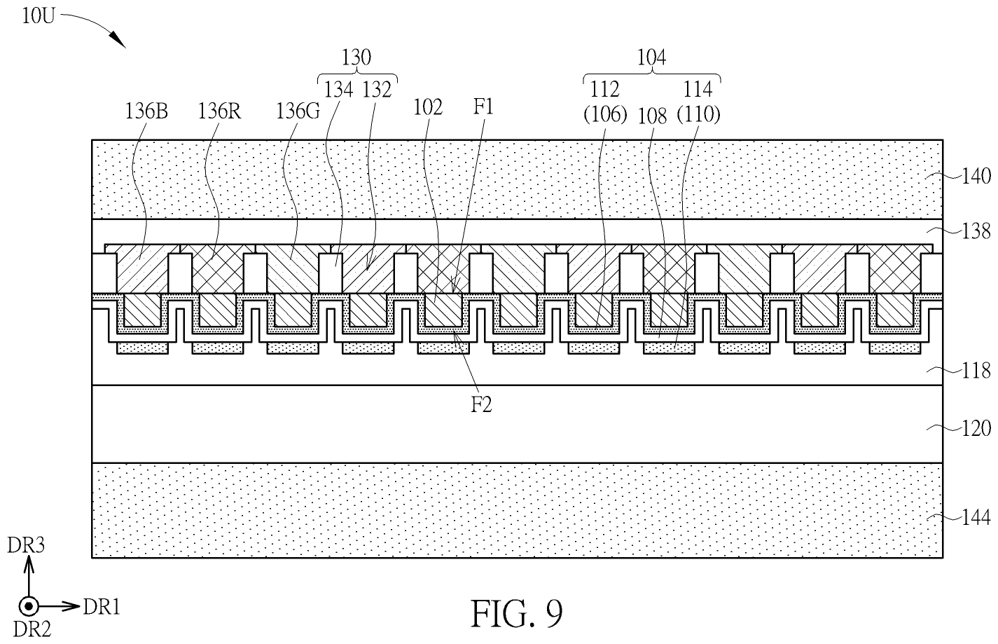

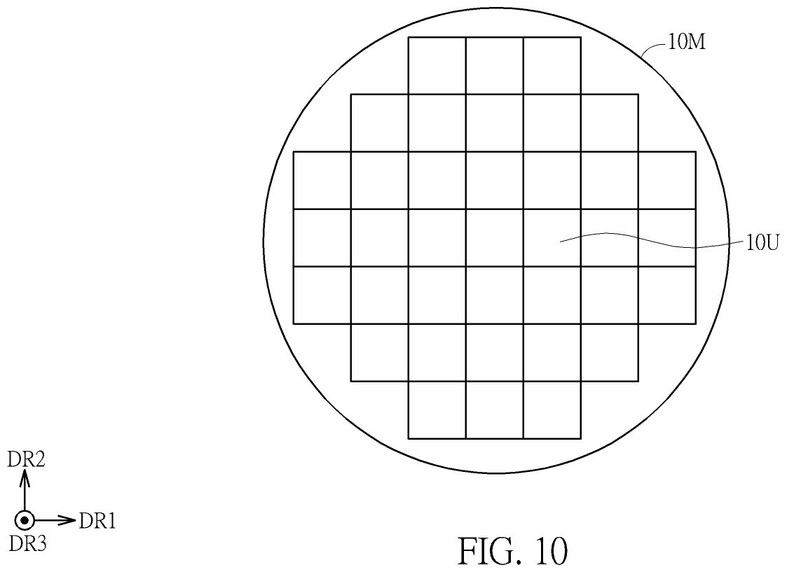

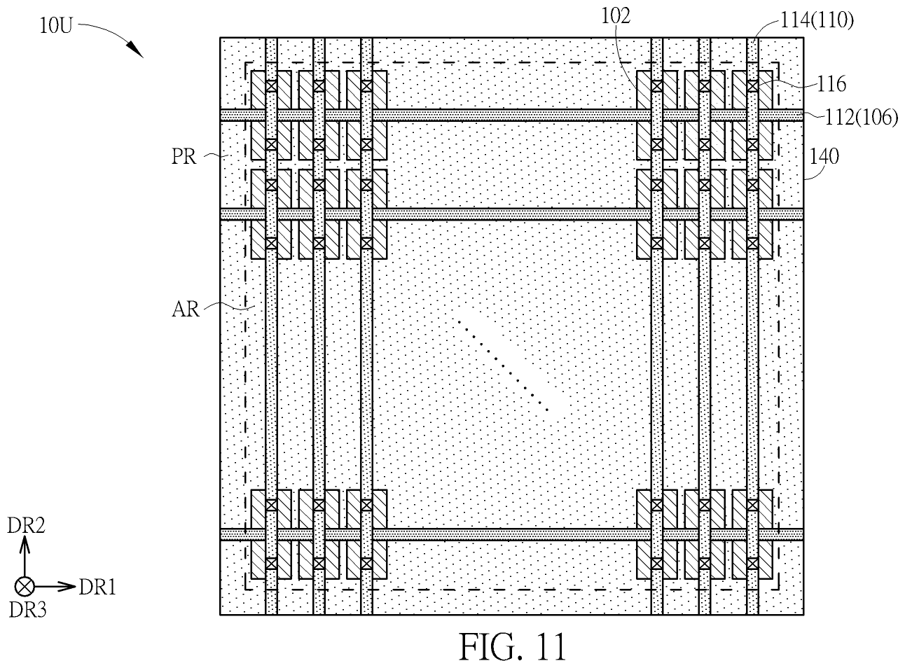

Referring to FIG. 1 to FIG. 13, FIG. 1 to FIG. 9 are schematic diagrams illustrating a manufacturing method of a display device according to a first embodiment of the present invention, FIG. 10 is a schematic diagram illustrating a top view of a display mother board including display panel units in the first embodiment of the present invention, and FIG. 11 is a schematic diagram illustrating a top view of one of the display panel units according to the first embodiment of the present invention. The top view in FIG. 11 can correspond to the substrate 140, the light emitting components 102 and the circuit layer 104 in FIG. 9.

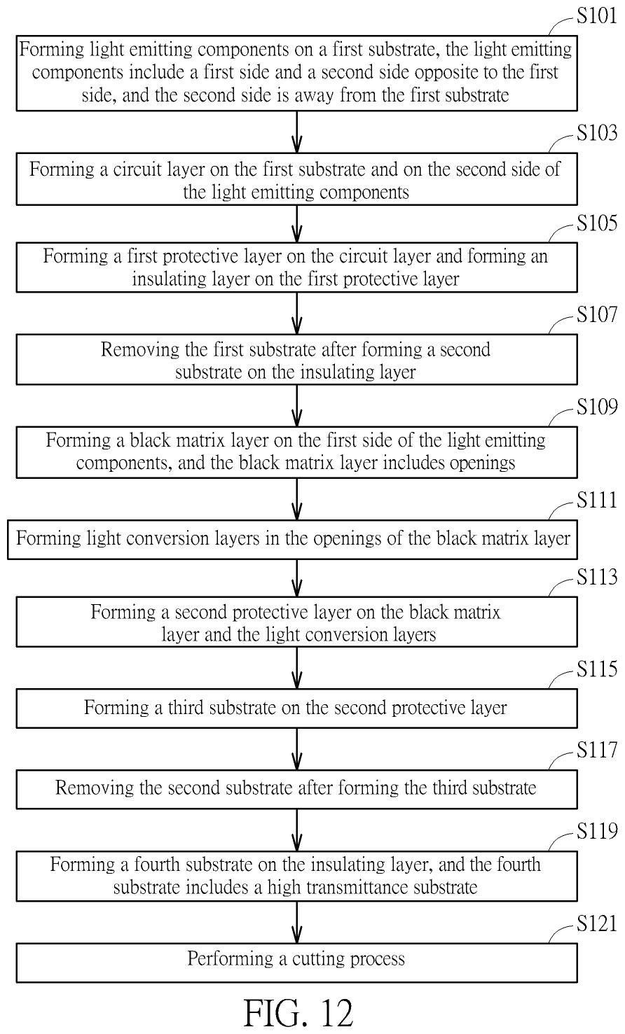

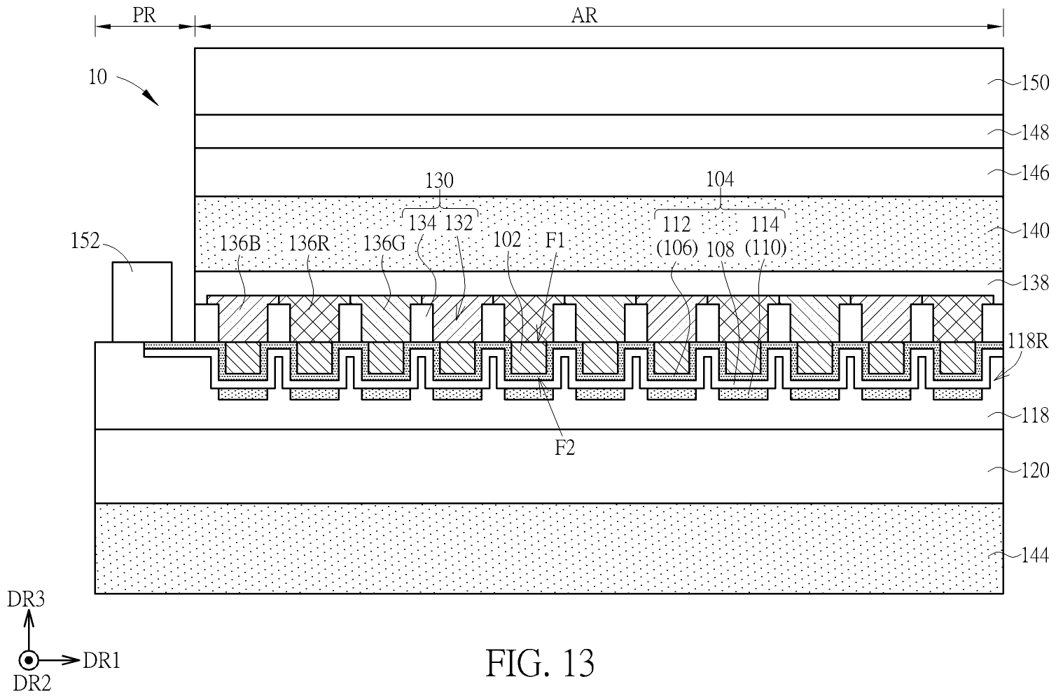

FIG. 12 is a flowchart of the manufacturing method of the display device according to the first embodiment of the present invention, and FIG. 13 is a schematic cross-sectional diagram illustrating the display device according to the first embodiment of the present invention. It should be understood that the steps shown in FIG. 12 may not be complete, and other steps may be performed before, after or between any shown steps. In addition, some steps may be performed simultaneously or in a different order from that shown in FIG. 12.

As shown in FIG. 1 and FIG. 12, a step S101 can be performed first to form a plurality of light emitting components 102 on the substrate 100, the light emitting components 102 include a first side F1 and a second side F2 opposite to the first side F1, and the second side F2 is away from the substrate 100. The first side F1 and the second side F2 can be opposite sides of the light emitting components 102 in the direction DR3, and the light emitting components 102 can be disposed on the surface 1001 of the substrate 100, but not limited thereto. The light emitting components 102 may include micro-light emitting diodes (micro-LEDs), but not limited thereto. The light emitting components 102 may also include other types of light emitting diodes. The light emitting components 102 may emit blue light or ultraviolet light, but not limited thereto.

The substrate 100 may be a rigid substrate, such as a sapphire substrate, but not limited thereto. In addition, the substrate 100 may be a wafer used for manufacturing the light emitting components 102. In the step S101, the process of manufacturing the light emitting components 102 may include epitaxy and chip processes, but not limited thereto.

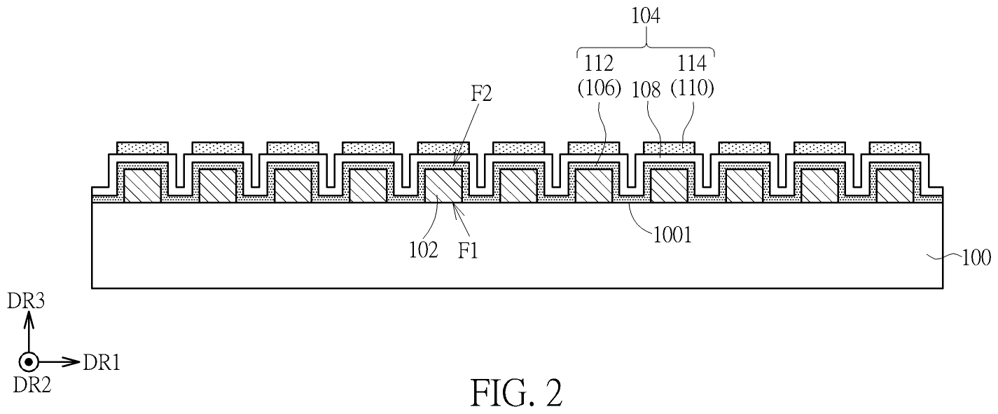

Next, as shown in FIG. 2 and FIG. 12, a step S103 can be performed to form a circuit layer 104 on the substrate 100 and on the second side F2 of the light emitting components 102. The manufacturing method of the circuit layer 104 can include following steps. Firstly, a first conductive layer 106 is formed on the substrate 100 and on the second side F2 of the light emitting components 102, and the first conductive layer 106 can cover the light emitting components 102 and a portion of the surface 1001 of the substrate 100. Next, an interlayer dielectric layer 108 is formed on the first conductive layer 106. The interlayer dielectric layer 108 may include an inorganic insulating material, an organic insulating material or a combination of the above, but not limited thereto.

Next, a second conductive layer 110 is formed on the interlayer dielectric layer 108, the first conductive layer 106 and the second conductive layer 110 can be electrically connected to the light emitting components 102, and the first conductive layer 106 can be electrically isolated from the second conductive layer 110. As shown in FIG. 2, the interlayer dielectric layer 108 can be disposed between the first conductive layer 106 and the second conductive layer 110 to electrically isolate the first conductive layer 106 from the second conductive layer 110.

As shown in FIG. 11, the first conductive layer 106 may include a plurality of first signal lines 112, and the second conductive layer 110 may include a plurality of second signal lines 114, but not limited thereto. The first signal lines 112 may extend in the direction DR1, and as shown in FIG. 2, the first signal lines 112 may be directly electrically connected to the light emitting components 102, but not limited thereto.

As shown in FIG. 11, the second signal lines 114 may extend in the direction DR2, and the second signal lines 114 may be electrically connected to the light emitting components 102 via through holes 116, but not limited thereto. For example, the through holes 116 can be formed in the interlayer dielectric layer 108 before the second conductive layer 110 is formed and after the interlayer dielectric layer 108 is formed, the second conductive layer 110 can be formed next, and the second conductive layer 110 can fill in the through holes 116 and can be electrically connected to the light emitting components 102, but not limited to thereto.

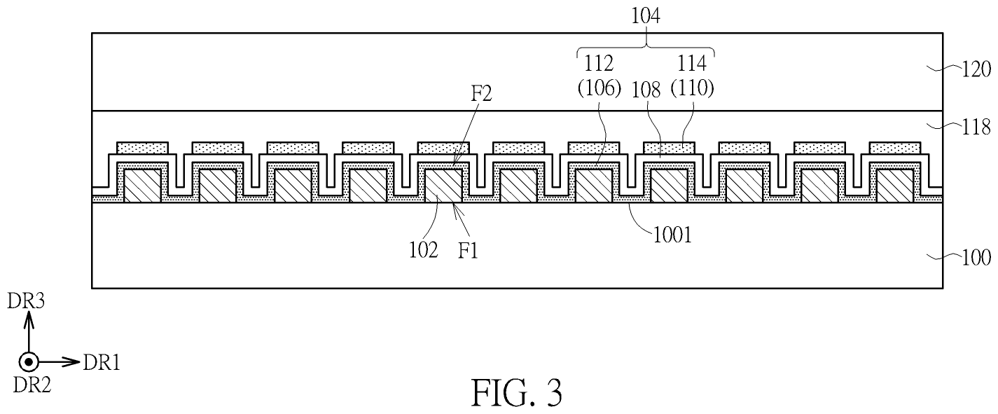

Next, as shown in FIG. 3 and FIG. 12, a step S105 can be performed to form a first protective layer 118 on the circuit layer 104 and form an insulating layer 120 on the first protective layer 118. The first protective layer 118 may cover the circuit layer 104 and the light emitting components 102, and the first protective layer 118 may be disposed between the circuit layer 104 and the insulating layer 120. The first protective layer 118 may include an inorganic insulating material, such as silicon oxide, silicon nitride or a combination of the above, but not limited thereto. The insulating layer 120 may include a material that can endure high temperature. Since other manufacturing steps will be subsequently performed, the insulating layer 120 cannot be too thick when considering the factor of thermal expansion. For example, the insulating layer 120 may include an organic insulating material such as polyimide (PI), but not limited thereto. The thickness of the insulating layer 120 may be greater than or equal to 10 micrometers and less than or equal to 20 micrometers, but not limited thereto.

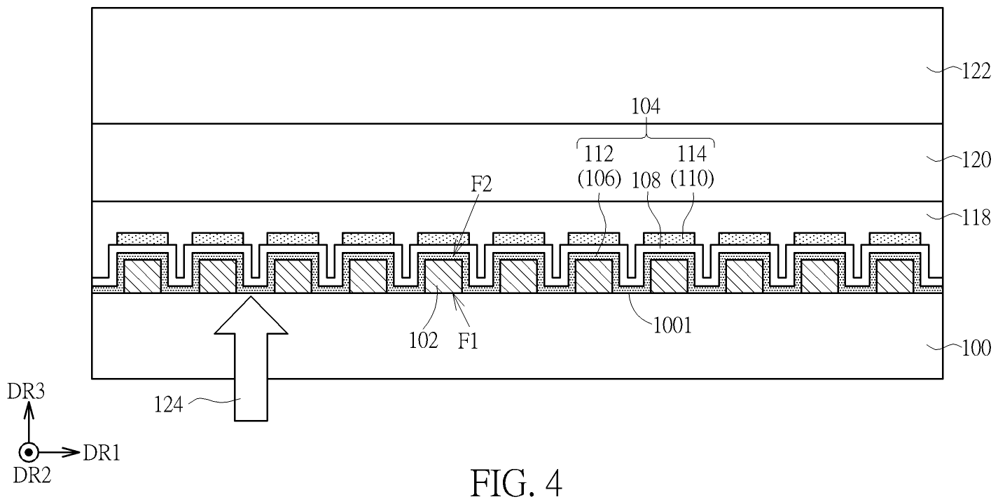

Next, as shown in FIG. 4 and FIG. 12, a step S107 can be performed to remove the substrate 100 after a substrate 122 is formed on the insulating layer 120. The substrate 122 may be a temporary substrate, and the substrate 122 may include the rigid substrate, such as a glass substrate, but not limited thereto. After the substrate 122 is formed, a laser lift-off process can be performed on the substrate 100, a laser 124 can be irradiated from a side of the substrate 100 away from the light emitting components 102 to remove the substrate 100 from the light emitting components 102 and the circuit layer 104.

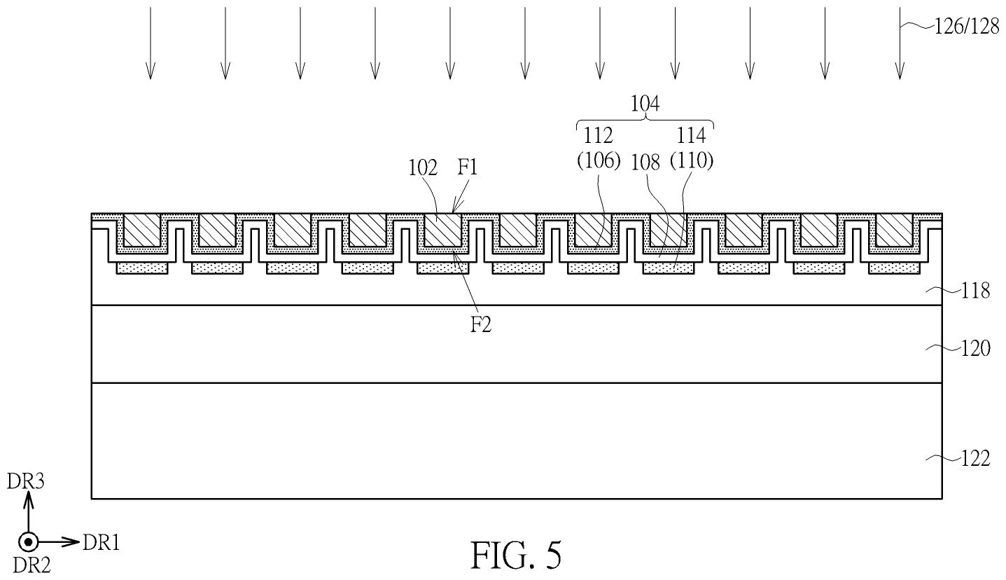

As shown in FIG. 5, after the substrate 100 is removed, the first side F1 of the light emitting components 102 can be reversed to be the upper side. In addition, a cleaning step 126 and a roughening step 128 can be performed on the first side F1 of the light emitting components 102 after the substrate 100 is removed and before a black matrix layer 130 is formed. In the cleaning step 126, the residual material (such as gallium) on the first side F1 of the light emitting components 102 can be removed, and the short circuit phenomenon can be avoided or the emitted light can be prevented from being absorbed by the residual material. The roughening step 128 can roughen the surfaces of the light emitting components 102, thereby increasing the light extraction efficiency.

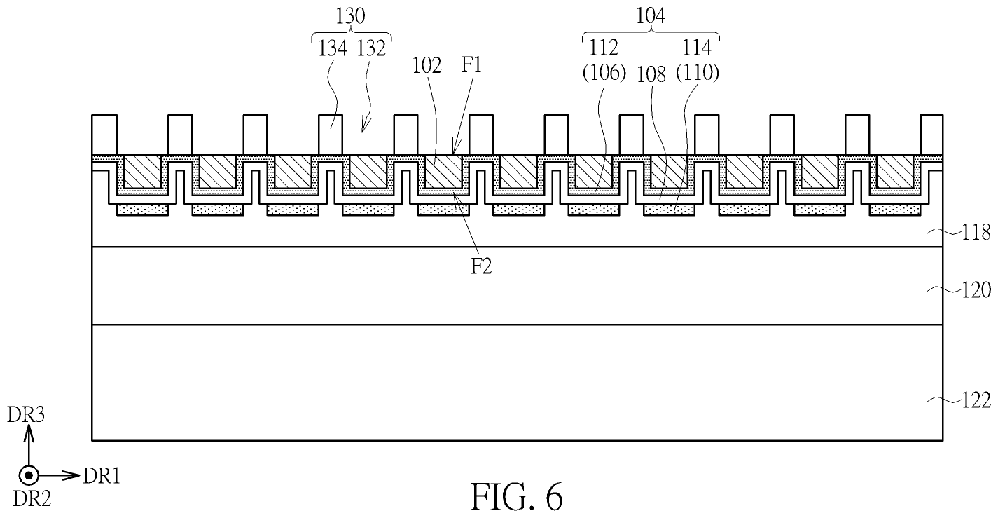

Next, as shown in FIG. 6 and FIG. 12, a step S109 can be performed to form the black matrix layer 130 on the first side F1 of the light emitting components 102, and the black matrix layer 130 includes a plurality of openings 132. One of the openings 132 may correspond to one of the light emitting components 102 in the direction DR3. A shielding portion 134 of the black matrix layer 130 may be disposed between adjacent light emitting components 102 or surround the light emitting components 102. The material of the black matrix layer 130 may include an opaque material such as photoresist, but not limited to this.

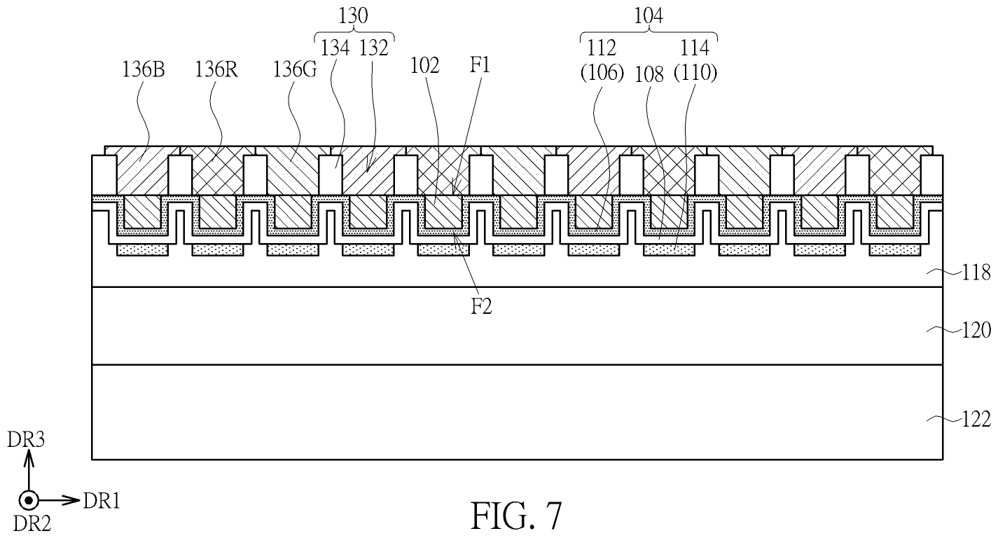

Next, as shown in FIG. 7 and FIG. 12, a step S111 can be performed to form a plurality of light conversion layers 136R, 136G and 136B in the openings 132 of the black matrix layer 130. In some embodiments, the manufacturing method of the light conversion layers 136R, 136G and 136B may include an inkjet print process. In other embodiments, the manufacturing method of the light conversion layers 136R, 136G and 136B may include an exposure and development process.

The light conversion layers 136R, 136G, and 136B may include quantum dots, but not limited thereto. The quantum dots in the light conversion layers 136R can convert the light of the light emitting components 102 into red light, the quantum dots in the light conversion layers 136G can convert the light of the light emitting components 102 into green light, and the quantum dots in the light conversion layers 136B can convert the light of the light emitting components 102 into blue light, but not limited thereto.

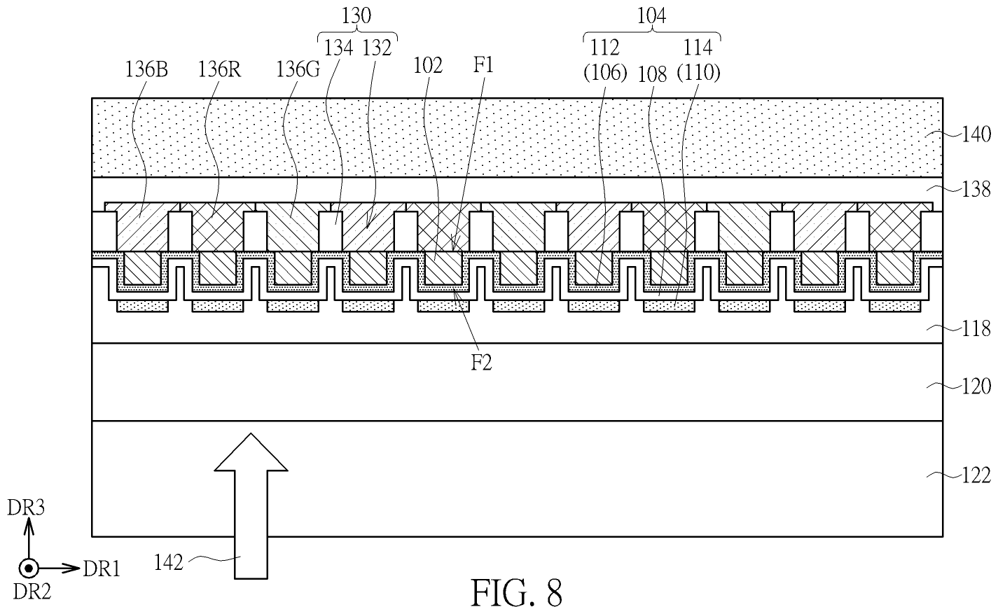

Next, as shown in FIG. 8 and FIG. 12, a step S113 can be performed to form a second protective layer 138 on the black matrix layer 130 and the light conversion layers 136R, 136G and 136B. The second protective layer 138 may include an inorganic insulating material such as silicon oxide, silicon nitride or a combination of the above, but not limited thereto. Next, a step S115 can be performed to form a substrate 140 on the second protective layer 138. The substrate 140 may include a high transmittance substrate. In the present invention, the transmittance of the high transmittance substrate may be greater than or equal to 90%, and the material of the high transmittance substrate may include, for example, polyethylene terephthalate (PET), triacetyl cellulose (TAC), cyclo olefin polymer (COP), polyimide or a combination of the above, but not limited thereto.

Next, as shown in FIG. 12, a step S117 can be performed to remove the substrate 122 after the substrate 140 is formed. As shown in FIG. 8, a laser lift-off process can be performed on the substrate 122, and a laser 142 can be irradiated on the side of the substrate 122 away from the insulating layer 120 to remove the substrate 122 from the lower surface of the insulating layer 120. Next, as shown in FIG. 9 and FIG. 12, a step S119 can be performed to form a substrate 144 on the lower surface of the insulating layer 120 or under the insulating layer 120, and the material of the substrate 144 can be the same as the material of the substrate 140, but not limited thereto.

After the step S119, a display mother board 10M including a plurality of display panel units 10U shown in FIG. 10 can be obtained. Next, a step S121 in FIG. 12 can be performed to separate the display panel units 10U in the display mother board 10M by a cutting process for obtaining separated display panel units 10U in FIG. 9 or FIG. 11. The cutting process may include a laser cutting, but not limited thereto. In addition, a space can be reserved in the display panel unit 10U for a driving component disposed in the display panel unit 10U later.

The manufacturing method of the display device is not limited to the above steps. As shown in FIG. 13, the manufacturing method of the display device may further include forming a polarizer 146 on the substrate 140, adhering a touch panel 148 to the polarizer 146, and forming a cover plate 150 on the touch panel 148. The touch panel 148 is disposed between the cover plate 150 and the polarizer 146. The polarizer 146 can be attached to the adjacent layers by pressure sensitive adhesives (PSA), but not limited thereto.

In addition, the manufacturing method of the display device may further include disposing a driving component 152 on the first protective layer 118, and the driving component 152 may be electrically connected to the first signal lines 112, but not limited to thereto. In other embodiments, the driving component 152 may be electrically connected to the second signal lines 114. For example, the driving component 152 can be an integrated circuit chip, but not limited thereto.

As shown in FIG. 13, a display device 10 of this embodiment may include the substrate 144, the substrate 140, the first protective layer 118, the light emitting components 102 and the circuit layer 104, but not limited thereto. In this embodiment, the substrate 140 and the substrate 144 may include flexible high transmittance substrates, and the display device 10 of this embodiment may be a flexible display device, but the present invention is not limited thereto. The substrate 140 may be disposed opposite to the substrate 144. For example, the materials of the substrates 140 and 144 may include PET, and the thicknesses of the substrates 140 and 144 may be about 90 micrometers, but not limited thereto.

The first protective layer 118 is disposed between the substrate 144 and the substrate 140, and the display device 10 may further include an insulating layer 120 disposed between the first protective layer 118 and the substrate 144. The first protective layer 118 includes a plurality of recesses 118R, and the light emitting components 102 are disposed in the recesses 118R of the first protective layer 118. For example, one of the light emitting components 102 can be disposed in one of the recesses 118R, but not limited thereto. The thickness of the light emitting component 102 may be about 10 micrometers, but not limited thereto.

The circuit layer 104 is disposed on the first protective layer 118 and extends into the recesses 118R. The circuit layer 104 can be electrically connected to the light emitting components 102, and a portion of the circuit layer 104 disposed in the recesses 118R can be disposed between the light emitting components 102 and the first protective layer 118. The circuit 104 includes the first conductive layer 106, the second conductive layer 110 and the interlayer dielectric layer 108, and the first conductive layer 106, the second conductive layer 110 and the interlayer dielectric layer 108 are disposed on the first protective layer 118. The first conductive layer 106 is disposed between the light emitting components 102 and the second conductive layer 110, and the interlayer dielectric layer 108 is disposed between the first conductive layer 106 and the second conductive layer 110.

The first conductive layer 106 (such as the first signal lines 112) may extend into the recesses 118R along the direction DR1. The second conductive layer 110 (such as the second signal lines 114) may extend into the recesses 118R along the direction DR2. Therefore, in a cross-sectional structure (as shown in FIG. 13), one of the first signal lines 112 of the first conductive layer 106 can be disposed on the first protective layer 118 and extend into the recesses 118R along the direction DR1, and the second signal lines 114 of the second conductive layer 110 can be respectively disposed in the recesses 118R.

As shown in FIG. 11, the first signal lines 112 of the first conductive layer 106 and the second signal lines 114 of the second conductive layer 110 can be electrically connected to the light emitting components 102. As shown in FIG. 13, the interlayer dielectric layer 108 is disposed on the first protective layer 118 and extends into the recesses 118R, and the first conductive layer 106 can be electrically isolated from the second conductive layer 110 by the interlayer dielectric layer 108.

Although the passive matrix display device is used as an example of the display device of the present invention, the present invention is not limited thereto. In other embodiments, the display device may be the active matrix display device and may include thin film transistors as the switches of the light emitting components 102.

As shown in FIG. 13, the display device 10 further includes the driving component 152 disposed on the first protective layer 118 and on one side of the light emitting components 102 in the direction DR1. For example, the display device 10 may include a display region AR and a peripheral region PR, the peripheral region PR may be disposed on at least one side of the display region AR, the light emitting components 102 may be disposed in the display region AR, and the driving component 152 may be disposed in the peripheral region PR. In addition, the circuit layer 104 may be extended from the display region AR to the peripheral region PR, and the circuit layer 104 may be electrically connected to the driving component 152. As shown in FIG. 13, the driving component 152 can be electrically connected to the first signal line 112 of the first conductive layer 106, but not limited thereto.

The display device 10 further includes the black matrix layer 130, the light conversion layers 136R, 136G and 136B, and the second protective layer 138. The black matrix layer 130 is disposed on the first protective layer 118 and the light emitting components 102, the black matrix layer 130 includes the openings 132, and the openings 132 are disposed on the light emitting components 102. The light conversion layers 136R, 136G, and 136B are disposed in the openings 132 of the black matrix layer 130 and disposed on and cover the light emitting components 102. The thicknesses of the light conversion layers 136R, 136G and 136B may be about 15 micrometers, but not limited thereto. In addition, the second protective layer 138 is disposed between the substrate 140 and the light conversion layers 136R, 136G and 136B.

The display device 10 further includes the polarizer 146, the touch panel 148 and the cover plate 150. The polarizer 146 is disposed on the substrate 140. The polarizer 146 can be a circular polarizer which can eliminate ambient light. The thickness of the polarizer 146 may be about 50 micrometers, but not limited thereto. The touch panel 148 is disposed on the polarizer 146, and the touch panel 148 may include the self-capacitance touch panel or the mutual-capacitance touch panel, but not limited thereto. The cover plate 150 is disposed on the touch panel 148, and the touch panel 148 is disposed between the cover plate 150 and the polarizer 146. The cover plate 150 may include ultra-thin glass (UTG) or colorless polyimide (CPI) film, but not limited thereto. The thickness of the cover plate 150 may be about 90 micrometers, but not limited thereto.

In the display device and the manufacturing method thereof of this embodiment, the light emitting components 102 and the circuit layer 104 are directly formed on the substrate 100 (e.g., the wafer used to manufacture the light emitting components 102). Therefore, the light emitting components 102 do not need to be transferred to the circuit board, which can solve the problems of poor precision and poor yield introduced by the mass transfer process, and being beneficial to manufacturing high pixels per inch (PPI) display devices or flexible display devices.

The display device and the manufacturing method thereof of the present invention are not limited to the aforementioned embodiments. The following will continue to disclose other embodiments of the present invention. However, in order to simplify the description and highlight the differences between the embodiments, the same reference numerals are used to denote the same elements hereinafter, and the repeated portions will not be described again.

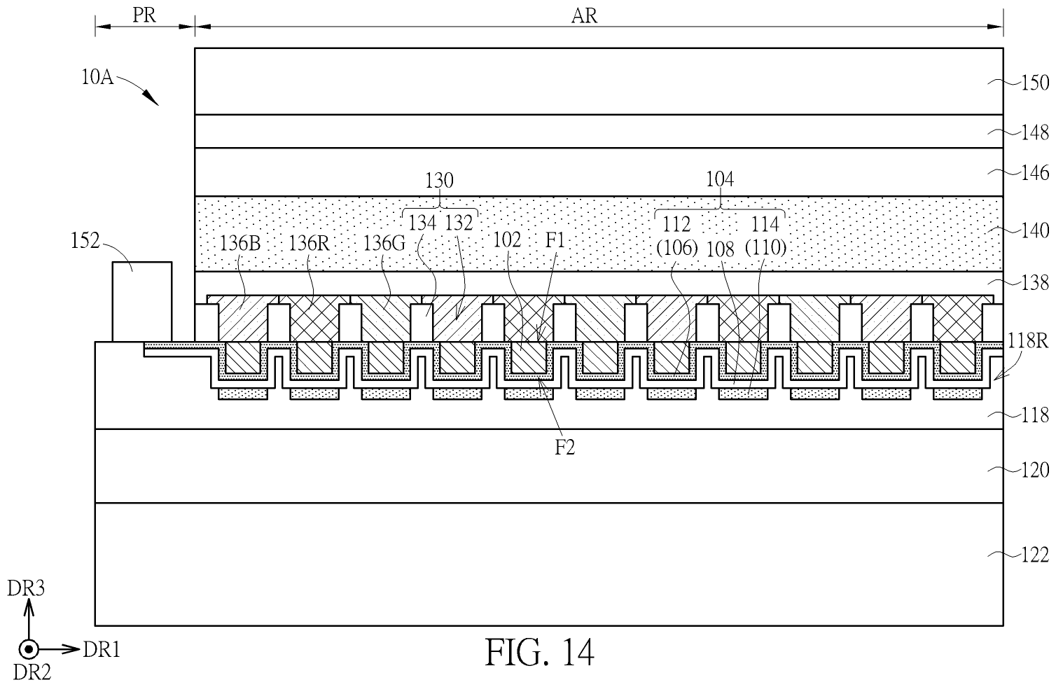

Referring to FIG. 14, FIG. 14 is a schematic cross-sectional diagram illustrating a display device according to a second embodiment of the present invention. The difference between this embodiment and the first embodiment is that the cutting process of the step S121 is performed after the step S115, and the steps S117 and S119 are omitted. The substrate 122 of this embodiment is not removed, thus the substrate 122 of this embodiment is not the temporary substrate. In addition, after the step S121 is performed, the polarizer 146, the touch panel 148 and the cover plate 150 are subsequently formed on the substrate 140 to obtain a display device 10A shown in FIG. 14.

In the display device 10A of this embodiment, the bottom substrate is the substrate 122 instead of the substrate 144. The substrate 122 may include a rigid high transmittance substrate, such as a glass substrate, and the thickness of the substrate 122 may be greater than or equal to 250 micrometers and less than or equal to 450 micrometers, but not limited thereto. Therefore, the display device 10A of this embodiment can be a non-flexible display device. In addition, in some embodiments, the substrate 140 may also be a glass substrate.

The manufacturing method of the display device of the present invention can be applied to manufacturing non-flexible display devices or flexible display devices. In the display device and the manufacturing method thereof of the present invention, the light emitting components and the circuit layer are directly formed on the wafer. Therefore, the light emitting components do not need to be transferred to the circuit board, which can solve the problems of poor precision and poor yield introduced by the mass transfer process, and being beneficial to manufacturing high PPI non-flexible display devices or high PPI flexible display devices.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a display device, comprising:
forming a plurality of light emitting components on a first substrate, wherein the light emitting components comprise a first side and a second side opposite to the first side, and the second side is away from the first substrate;
forming a circuit layer on the first substrate and on the second side of the light emitting components;
forming a first protective layer on the circuit layer and forming an insulating layer on the first protective layer;
removing the first substrate after forming a second substrate on the insulating layer;
forming a black matrix layer on the first side of the light emitting components, wherein the black matrix layer comprises a plurality of openings;
forming a plurality of light conversion layers in the openings of the black matrix layer;
forming a second protective layer on the black matrix layer and the light conversion layers; and
forming a third substrate on the second protective layer.

2. The manufacturing method of the display device according to claim 1, further comprising:
removing the second substrate after forming the third substrate; and
forming a fourth substrate on the insulating layer, wherein the fourth substrate comprises a high transmittance substrate, and a transmittance of the high transmittance substrate is greater than or equal to 90%.

3. The manufacturing method of the display device according to claim 1, wherein a manufacturing method of the circuit layer comprises:
forming a first conductive layer on the first substrate and on the second side of the light emitting components;
forming an interlayer dielectric layer on the first conductive layer; and
forming a second conductive layer on the interlayer dielectric layer, wherein the first conductive layer and the second conductive layer are electrically connected to the light emitting components, and the first conductive layer is electrically isolated from the second conductive layer.

4. The manufacturing method of the display device according to claim 1, wherein the light emitting components comprise a plurality of micro-light emitting diodes.

5. The manufacturing method of the display device according to claim 1, wherein the first substrate comprises a sapphire substrate.

6. The manufacturing method of the display device according to claim 1, wherein the first protective layer and the second protective layer comprise an inorganic insulating material.

7. The manufacturing method of the display device according to claim 1, wherein the insulating layer comprises an organic insulating material, and the thickness of the insulating layer is greater than or equal to 10 micrometers and less than or equal to 20 micrometers.

8. The manufacturing method of the display device according to claim 1, wherein the second substrate comprises a glass substrate.

9. The manufacturing method of the display device according to claim 1, wherein the third substrate comprises a high transmittance substrate, and a transmittance of the high transmittance substrate is greater than or equal to 90%.

10. The manufacturing method of the display device according to claim 1, wherein a manufacturing method of the light conversion layers comprises an inkjet print process or an exposure and development process.

11. The manufacturing method of the display device according to claim 1, further comprising performing a cleaning step and a roughening step on the first side of the light emitting components after removing the first substrate and before forming the black matrix layer.

12. The manufacturing method of the display device according to claim 1, further comprising:
forming a polarizer on the third substrate;
adhering a touch panel to the polarizer; and
forming a cover plate on the touch panel, wherein the touch panel is disposed between the cover plate and the polarizer.

13. A display device, comprising:
a first substrate;
a second substrate, disposed opposite to the first substrate;
a first protective layer, disposed between the first substrate and the second substrate, wherein the first protective layer comprises a plurality of recesses;
a plurality of light emitting components, disposed in the recesses of the first protective layer; and
a circuit layer, disposed on the first protective layer and extending into the recesses, wherein the circuit layer is electrically connected to the light emitting components, and a portion of the circuit layer is disposed between the light emitting components and the first protective layer.

14. The display device according to claim 13, wherein the circuit layer comprises:
a first conductive layer, disposed on the first protective layer and extending into the recesses;
a second conductive layer, disposed in the recesses of the first protective layer, wherein the first conductive layer is disposed between the light emitting components and the second conductive layer; and
an interlayer dielectric layer, disposed on the first protective layer and extending into the recesses, wherein the interlayer dielectric layer is disposed between the first conductive layer and the second conductive layer,
wherein the first conductive layer and the second conductive layer are electrically connected to the light emitting components, and the first conductive layer is electrically isolated from the second conductive layer.

15. The display device according to claim 13, further comprising a driving component disposed on the first protective layer and on one side of the light emitting components, wherein the circuit layer is electrically connected to the driving component.

16. The display device according to claim 13, further comprising:
a black matrix layer, disposed on the first protective layer and the light emitting components, wherein the black matrix layer includes a plurality of openings; and
a plurality of light conversion layers, disposed in the openings of the black matrix layer.

17. The display device according to claim 16, further comprising a second protective layer disposed between the light conversion layers and the second substrate.

18. The display device according to claim 13, further comprising an insulating layer disposed between the first protective layer and the first substrate.

19. The display device according to claim 13, further comprising:
a polarizer, disposed on the second substrate;
a touch panel, disposed on the polarizer; and
a cover plate, disposed on the touch panel, wherein the touch panel is disposed between the cover plate and the polarizer.

20. The display device according to claim 13, wherein the first substrate and the second substrate respectively comprise a high transmittance substrate, and a transmittance of the high transmittance substrate is greater than or equal to 90%.
